(19) United States
(12) Patent Application Publication
(10) Pub. No.: US 2025/0331398 A1
(43) Pub. Date: Oct. 23, 2025

(54) ENCAPSULATION ASSEMBLY, MANUFACTURING METHOD AND DISPLAY DEVICE

(71) Applicant: HKC CORPORATION LIMITED, Shenzhen (CN)

(72) Inventors: Feng JIANG, Shenzhen (CN); Qiang LENG, Shenzhen (CN); Longping WANG, Shenzhen (CN); Haiyang LI, Shenzhen (CN); Liu HE, Shenzhen (CN); Anyan ZHANG, Shenzhen (CN); Lidan YE, Shenzhen (CN)

(21) Appl. No.: 19/170,556

(22) Filed: Apr. 4, 2025

(30) Foreign Application Priority Data
Apr. 18, 2024 (CN) 202410467187.X

(51) Int. Cl. H10K 59/80

(52) U.S. Cl. CPC H10K 59/873; H10K 59/8722

(57) ABSTRACT

An encapsulation assembly is used for encapsulating a display module, the display module includes a first substrate and a second substrate opposite to each other, and the display module further comprises a display region and a non-display region provided around the display region. The encapsulation assembly includes an elastic encapsulation member provided between the first substrate and the second substrate and located in the non-display region, the elastic encapsulation member includes two bending deformation portions connected to each other and bent in opposite directions.

### CROSS-REFERENCE TO RELATED APPLICATIONS

This application claims priority to Chinese Patent Application No. 202410467187.X, filed on Apr. 18, 2024, the entire disclosure of which is hereby incorporated herein by reference.

### TECHNICAL FIELD

The present application belongs to the field of display technology, and specifically relates to an encapsulation assembly, a manufacturing method and a display device.

### BACKGROUND

In the display module, some of the structures located on the display region have the property of being easily oxidized, for example, the cathode, organic self-luminous material and other structures located on the display region are usually made of materials that are easily oxidized. When the structures on the display region are oxidized, it is easy to accelerate the aging of the display module, which will shorten the service life of the display module.

In order to solve the above problem, the existing technical means is to bond a curing adhesive between the first substrate and the second substrate of the display module that are opposite to each other in the up and down, to encapsulate the display region of the display module, but the curing adhesive of the display module encapsulated by such encapsulation means easily deforms under the action of an external pressure, and a gap is generated between the first substrate and the second substrate. Therefore, the existing encapsulation means still cannot avoid the entry of external air and moisture into the display region to cause oxidative corrosion of the structures in the display region.

### SUMMARY

There are provided an encapsulation assembly, a manufacturing method, and a display device according to embodiments of the present disclosure. The technical solution is as below:

According to a first aspect of embodiments of the present application, there is provided an encapsulation assembly, for encapsulating a display module, the display module includes a first substrate and a second substrate opposite to each other, and the display module further includes a display region and a non-display region provided around the display region;
the encapsulation assembly includes:
an elastic encapsulation member, provided between the first substrate and the second substrate and located in the non-display region, the elastic encapsulation member includes two bending deformation portions connected to each other and bent in opposite directions;
one of the two bending deformation portions is connected to the first substrate, and another one of the two bending deformation portions is connected to the second substrate;
a plurality of the elastic encapsulation members are sequentially arranged between the non-display region and the display region in a direction from the non-display region to the display region; and
the plurality of the elastic encapsulation members are sequentially abutted against each other, two adjacent bending deformation portions are bent in a same direction, and a concave surface of one of the two adjacent bending deformation portions is closely spliced with a convex surface of another one of the two adjacent bending deformation portions.

According to a second aspect of embodiments of the present application, there is provided a method for manufacturing an encapsulation assembly, the encapsulation assembly is configured for encapsulating a display module, the display module includes the first substrate and the second substrate opposite to each other, and the display module further comprises a display region and a non-display region provided around the display region;
the method includes:
providing the display module, and preparing an initial elastic encapsulation member on the first substrate and/or the second substrate;
providing the first substrate and the second substrate opposite to each other and pressing the first substrate and the second substrate together, the initial elastic encapsulation member is bonded between the first substrate and the second substrate to form an elastic encapsulation member, the elastic encapsulation member have two bending deformation portions connected to each other, and the two bending deformation portions are bent in opposite directions;
the elastic encapsulation member has two bending deformation portions connected to each other, the two bending deformation portions are bent in opposite directions, and one of the two bending deformation portions is connected to the first substrate, and another one of the two bending deformation portions is connected to the second substrate;
arranging a plurality of the elastic encapsulation members sequentially in a direction from the non-display region to the display region; and
two adjacent elastic encapsulation members are sequentially abutted against each other, two adjacent bending deformation portions are bent in a same direction, and a concave surface of one of the two adjacent bending deformation portions is closely spliced with a convex surface of another one of the two adjacent bending deformation portions.

It should be understood that the above general description and the detailed description that follows are merely exemplary and explanatory, and do not limit the present application.

### BRIEF DESCRIPTION OF THE DRAWINGS

The accompanying drawings herein are incorporated into and form a part of the specification, illustrate embodiments in accordance with the present application, and are used in conjunction with the specification to explain the principles of the present application. It will be apparent that the accompanying drawings in the following description are only some of the embodiments of the present application, and that other accompanying drawings may be obtained from these drawings without creative labor for those skilled in the art.

FIG. 1 is a sectional structure view of an encapsulation assembly in an embodiment of the present application.

FIG. 2 is a sectional structure view of the elastic encapsulation member and the filling member in the embodiment of the present application.

FIG. 3 is a sectional structure view of an elastic encapsulation member in a groove in an embodiment of the present application.

FIG. 4 is a sectional structure view of the evaporation member and the elastic encapsulation member in an embodiment of the present application.

FIG. 5 is a sectional structure view of a frame adhesive and the encapsulation assembly in the display module in the embodiment of the present application.

FIG. 6 is another sectional structure view of the frame adhesive and the encapsulation assembly in the display module in the embodiment of the present application.

FIG. 7 is a flowchart of manufacturing the encapsulation assembly in the embodiment of the present application.

### DETAILED DESCRIPTION OF THE EMBODIMENTS

Embodiments will now be described more fully with reference to the accompanying drawings. However, the embodiments are capable of being implemented in a variety of forms and should not be construed as being limited to the examples set forth herein; rather, these embodiments allow for the present application to be more comprehensive and complete and conveys the idea of the embodiments in a comprehensive manner to those skilled in the art.

In addition, the described features, structures, or characteristics may be combined in one or more embodiments in any suitable manner. In the following description, many specific details are provided thereby giving a full understanding of the embodiments of the present application. However, those skilled in the art will realize that the technical solutions of the present application can be practiced without one or more of the specific details, or other methods, components, devices, steps, etc. can be employed. In other cases, the well-known methods, devices, implementations, or operations are not shown or described in detail to avoid obscuring aspects of the present application.

The present application is described in further detail below in conjunction with the accompanying drawings and specific embodiments. It should be noted herein that the technical features involved in the various embodiments of the present application described below may be combined with each other, as long as they do not constitute a conflict with each other. The embodiments described below by reference to the accompanying drawings are exemplary and are intended to be used for explaining the present application and are not to be construed as a limitation of the present application.

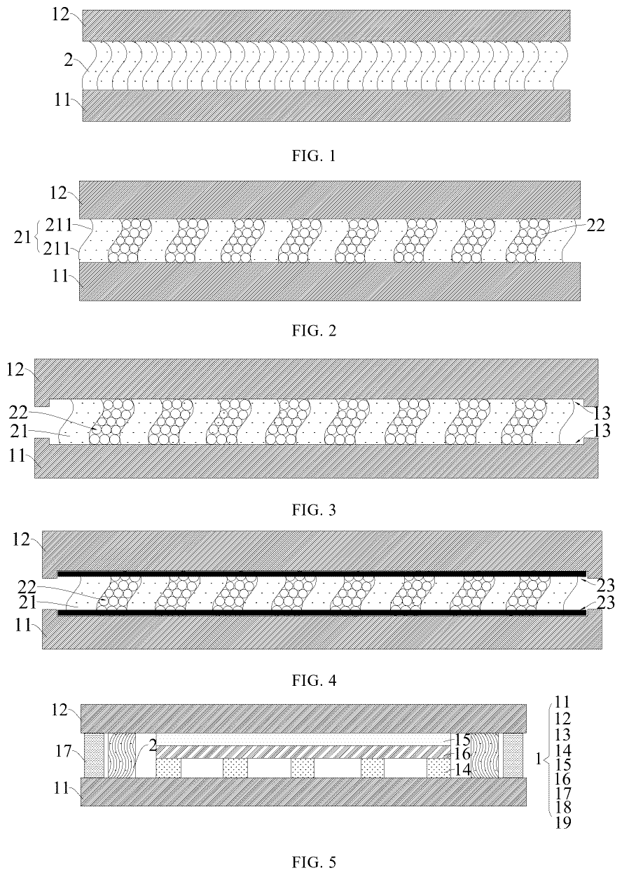

As shown in FIGS. 1 to 5, the present application provides an encapsulation assembly 2 for encapsulating a display module 1.

The display module 1 includes a first substrate 11 and a second substrate 12 opposite to each other, and the display module 1 further includes a display region and a non-display region provided around the display region.

As shown in FIG. 1, the encapsulation assembly 2 includes an elastic encapsulation member 21 provided between the first substrate 11 and the second substrate 12 and provided in the non-display region, and the elastic encapsulation member 21 has at least one bending deformation portion 211.

Specifically, the elastic encapsulation member 21 may be provided around the display region and connected to the first substrate 11 and the second substrate 12, so that the elastic encapsulation member 21, the first substrate 11, and the second substrate 12 may enclose to form a closed space. The closed space may isolate the display region of the display panel from the outside to reduce the contact of the external moisture and the structures in the display region and avoid the oxidative corrosion to structures in the display region caused by the external moisture. In addition, since the elastic encapsulation member 21 is provided in the non-display region, the shielding of the display region by the elastic encapsulation member 21 can be reduced, thereby improving the display brightness and the display effect of the display module 1.

It is to be noted that the bending deformation portion 211 in the embodiments of the present application may be an arch shape, so that when the first substrate 11 or the second substrate 12 is subjected to an external pressure and the pressure is transmitted to the bending deformation portion 211, the bending deformation portion 211 may spread the pressure received to various places in the interior to improve the pressure-resistant capability of the encapsulation module 2, thereby reducing the deformation generated when the bending deformation portion 211 is subjected to an external force, and thus the possibility of occurrence of a gap between the encapsulation assembly 2 and the first substrate 11 and the second substrate 12 to cause moisture to enter into the display region can be reduced, thereby reducing the risk of the oxidative corrosion to the structures in the display region caused by the external moisture, to extend the service life of the display module 1. However, without limitation, the bending deformation portion 211 in the embodiments of the present application may also be provided in a shape with tension other than an arch shape, to reduce the deformation of the encapsulation assembly 2 by the bending deformation portion 211 when the encapsulation assembly 2 is pressed by an external force, and to reduce the possibility of occurrence of a gap between the encapsulation assembly 2 and the first substrate 11 and the second substrate 12.

In addition, the embodiment of the present application provides the bending deformation portion 211 between the first substrate 11 and the second substrate 12, so that when a large amount of moisture is collected on the surface of the bending deformation portion 211, the moisture slides down to the first substrate 11 or the second substrate 12 along the arched surface of the bending deformation portion 211, thereby reducing the risk of the moisture being attached to the surface of the bending deformation portion 211 for a long period of time to cause the adhesive property between the encapsulation assembly 2 and the first substrate 11 and the second substrate 12 to weaken, and also reducing the risk of moisture infiltrating the bending deformation portion 211 after being attached to the surface of the bending deformation portion 211 for a long time, and then reducing the risk of the oxidative corrosion to the structures in the display region by the external moisture, to extend the service life of the display module 1.

Further, the embodiments of the present application may connect the curved surface of the bending deformation portion 211 with the first substrate 11 and the second substrate 12, so that the contact surface between the encapsulation module 2 and the first substrate 11 and the second substrate 12 can be enlarged, and the contact stresses between the first substrate 11 and the encapsulation module 2 and the contact stresses between the second substrate 12 and the encapsulation module 2 can be reduced to reduce the risk of the encapsulation module 2, the first substrate 11, and the second substrate 12 occurring a great deformation, even being broken, etc. due to excessive contact stresses, thereby extending the service life of the display module 1 and the encapsulation assembly 2.

In the embodiments of the present application, the flexible encapsulation material with tension can be used to produce the elastic encapsulation member 21, for example, ultraviolet (UV) curing glue can be used to produce the elastic encapsulation member 21, but not limited to this, the use of flexible encapsulation material with tension other than the UV curing glue to produce the elastic encapsulation member 21 are included in the scope of the embodiments of the present application.

Taking the use of UV curing glue to produce the elastic encapsulation member 21 as an example, the material has high process applicability, good adhesive properties and high temperature and high humidity resistance, which can enable the elastic encapsulation member 21 to maintain stable adhesion with the first substrate 11 and the second substrate 12 under high temperature and high humidity environments to effectively reduce the possibility that the elastic encapsulation member 21 melts or its' the adhesive force is reduced to fall off from the first substrate 11 and the second substrate 12. And the UV curing adhesive also has good hydrophobicity, the elastic encapsulation 21 and water exclude mutually, thus effectively blocking moisture penetration of the elastic encapsulation 21 cause oxidative corrosion to the structure in the display region.

In addition, the UV curing glue also has the characteristics of bending resistance and strong shear force, and the use of this material to form the elastic encapsulation member 21 can improve the toughness and compression resistance of the elastic encapsulation member 21, thereby avoiding fracture of the encapsulation assembly 2 when the display module 1 is subjected to pressure, and avoiding the elastic encapsulation member 21 from undergoing a great deformation, thereby reducing the possibility of occurrence of a gap between the encapsulation assembly 2 and the first substrate 11 and the second substrate 12, and reducing the risk of the external moisture entering into the display region to form oxidative corrosion to the structures in the display region.

In the embodiments of the present application, the elastic encapsulation member 21 may include two bending deformation portions 211 connected to each other and bent in opposite directions, but not limited thereto. The elastic encapsulation member 21 may also be provided with one or more than three bending deformation portions 211, and the two bending deformation portions 211 connected to each other are bent in opposite directions. The bending deformation portions 211 in the elastic encapsulation member 21 are connected to the first substrate 11 and the second substrate 12, respectively, and form a support for the first substrate 11 and the second substrate 12. In the embodiment of the present application, the number of the bending deformation portions 211 in the elastic encapsulation member 21 can be provided according to the actual situation.

The elastic encapsulation member 21 includes two bending deformation portions 211, for example, the two bending deformation portions 211 are connected to each other and are bent in opposite directions, and the elastic encapsulation member 21 as a whole can be viewed as an S-shaped curve. When the display module 1 is subjected to external pressure, and the pressure is transmitted to the elastic encapsulation member 21 by the first substrate 11 and the second substrate 12. The bending deformation portion 211 on the elastic encapsulation member 21 can spread the pressure to the interior, to reduce the stress concentrated at an end of the elastic encapsulation member 21 close to the first substrate 11 or the second substrate 12, which leads to a situation that the elastic encapsulation member 21 have a larger deformation or even is broken, and then reduce the possibility of the moisture entering into the display region by the elastic encapsulation member 21 to cause an oxidative corrosion to the structure in the display region. After the external force disappears, the pressure inside the bending deformation portion 211 is quickly spread to the end of the bending deformation portion 211 close to the first substrate 11 and the second substrate 12, i.e., in the whole process of being squeezed by the external force and the disappearance of the external force, the elastic encapsulation member 21 can make use of the shape of the bending deformation portion 211 to quickly spread the force to the interior, so as to balance the pressure at everywhere in the interior of the bending deformation portion 211, and improve the pressure resistance of the encapsulation assembly 2. In the whole process of pressure by the external force and disappearance of the external force, the encapsulation assembly 2 maintains the connection between the encapsulation assembly 2 and the first substrate 11 and the second substrate 12 to maintain the sealing between the encapsulation assembly 2 and the first substrate 11 and the second substrate 12, thereby reducing a gap generated between the elastic encapsulation member 21 and the first substrate 11 and the second substrate 12, because the gap can cause moisture to enter into the display region to cause oxidative corrosion to the structure in the display region, such that the service life of the display module 1 is extended.

In addition, when pressed by an external force, the encapsulation assembly 2 and the first substrate 11 and the second substrate 12 are pressed against each other, and the connection between the encapsulation assembly 2 and the first substrate 11 and the second substrate 12 is more closely connected, so that the possibility of occurrence of a gap between the elastic encapsulation member 21 and the first substrate 11 and the second substrate 12 can also be reduced, and the possibility of the moisture entering into the display region to cause oxidative corrosion to structures in the display region can be reduced.

In the embodiments of the present application, one bending deformation portion 211 can be connected to the first substrate 11, and another bending deformation portion 211 can be connected to the second substrate 12.

To illustrate, an outer surface of the bending deformation portion 211 is bent to form a certain curve. Since the bending deformation portion 211 is connected to the first substrate 11 and the second substrate 12, the contact surface between the elastic encapsulation member 21 and the first substrate 11 and the second substrate 12 can be increased, thereby reducing the contact stress between the elastic encapsulation member 21 and the first substrate 11 and the second substrate 12, such that the elastic encapsulation member 21, the first substrate 11 and the second substrate 12 are fractured due to large contact stress.

Further, a plurality of elastic encapsulation members 21 may be provided in the embodiments of the present application, and the plurality of elastic encapsulation members 21 are sequentially arranged from the non-display region to the display region.

Since the plurality of elastic encapsulation members 21 are provided sequentially in the direction from the non-display region to the display region, the connection surface between the elastic encapsulation member 21 and the first substrate 11 and the second substrate 12 can be increased to improve the solidity of the connection between the elastic encapsulation member 21 and the first substrate 11 and the second substrate 12, to reduce the possibility of occurrence of a gap between the encapsulation assembly 2 and the first substrate 11 and the second substrate 12, because the gap can cause the entry of moisture into the display region, so that the risk of moisture causing oxidative corrosion to the structures in the display region can be reduced, and the service life of the display module 1 can be extended. And since the plurality of elastic encapsulation members 21 are provided sequentially in the direction from the non-display region to the display region, the barrier between the display region and the outside is strengthened, and the external moisture entering into the display region needs to pass through the plurality of elastic encapsulation members 21, which improves the difficulty of the external moisture entering into the display region, strengthens the ability of the encapsulation assembly 2 to isolate moisture, and thus reduces the risk of oxidative corrosion to the devices in the display region caused by the moisture.

In addition, since the plurality of elastic encapsulation members 21 can improve the support effect of the encapsulation assembly 2 for the first substrate 11 and the second substrate 12 to reduce the contact stress between the encapsulation assembly 2 and the first substrate 11 and the second substrate 12 when the display module 1 is subjected to an external force, thereby reducing the occurrence of the encapsulation assembly 2, the first substrate 11, and the second substrate 12 being fractured under the action of an external force, to extend the service life of the display module 1 and the encapsulation assembly 2.

In the embodiments of the present application, each elastic encapsulation member 21 may be abutted against each other sequentially, and the two adjacent bending deformation portions 211 are bent. However, without limitation, in the embodiments of the present application, the elastic encapsulation members 21 may also be spaced apart from each other.

It is to be illustrated that when the elastic encapsulation members 21 are sequentially abutted against each other, the number, size and bending direction of the bending deformation portions 211 in the elastic encapsulation members 21 are the same, so that the elastic encapsulation members 21 can be tightly spliced together, and the elastic encapsulation members 21 can form a support for each other when the encapsulation assembly 2 is subjected to an external force, so that while the support force of the encapsulation assembly 2 for the first substrate 11 and second substrate 12 is improved, the overall pressure resistance of the encapsulation assembly 2 and the solidity of the connection between the encapsulation assembly 2 and the first substrate 11 and the second substrate 12 can also be improved to reduce the possibility of the encapsulation assembly 2 being fractured after being pressed by the external force or the possibility of occurrence of a gap between the encapsulation assembly 2 and the first substrate 11 and the second substrate 12, so as to reduce the risk of the external moisture entering into the display region to cause oxidative corrosion to the structure of the display region, to extend the service life of the display module 1.

In addition, as shown in FIG. 2, when the elastic encapsulation members 21 are spaced apart, the encapsulation assembly 2 may also include a filling member 22 or a mold, the filling member 22 or the mold is provided between two adjacent elastic encapsulation members 21.

Specifically, the filling member 22 or the mold provided between the two adjacent elastic encapsulation members 21 may be made of a hard encapsulation material with high structural strength, e.g., the filling member 22 may be made by using a moisture curing glue, but is not limited to this, and the use of a hard encapsulation material with high structural strength other than the moisture curing glue for making the elastic encapsulation members 21 is included in the scope of the embodiments of the present application.

Taking the use of moisture curing glue to make the elastic encapsulation member 21 as an example, the glue has a high glass transition temperature and high and low temperature cycling resistance. When the display module 1 is in a low temperature or high temperature working state, the filling member 22 always remains solid. When the encapsulation assembly 2 is subjected to an external pressure, the elastic encapsulation member 21 in the bending deformation portion 211 bends to a certain extent due to its own structural characteristics, the material hardness of the filling member 22 is greater than the bending deformation portion 211, so that during the bending process of the elastic encapsulation member 21, the filling member 22 can form a support for the elastic encapsulation member 21 to improve the pressure resistance of the encapsulation assembly 2, to reduce the deformation of the elastic encapsulation member 21, and reduce the possibility of occurrence of a gap between the elastic encapsulation member 21 and the first substrate 11 and the second substrate 12, so as to reduce the risk of moisture entering into the display region to cause oxidative corrosion to the structure of the display region, to extend the service life of the display module 1.

When the filling member 22 is provided between adjacent elastic encapsulation members 21, the filling member 22 can also be connected to the first substrate 11 and the second substrate 12. Since the moisture curing glue also has excellent bonding properties and water-oxygen barrier properties, in a certain high temperature or humid environment, the elastic encapsulation member 21 can still maintain the stability of the connection between the elastic encapsulation member 1 and the display module 1, so that the filling member 22 can work together with the elastic encapsulation member 21 to strengthen the encapsulation assembly 2 to strengthen the ability of the encapsulation assembly 2 to block moisture from entering into the display region and the solidity of the connection between the encapsulation assembly 2 and the first substrate 11 and the second substrate 12.

As shown in FIG. 3, in this embodiment of the present application, the first substrate 11 and the second substrate 12 may be provided with a groove 13 on a side close to the encapsulation assembly 2, and the encapsulation assembly 2 is provided in the groove 13.

Specifically, the groove 13 may be provided on the side of the first substrate 11 close to the encapsulation assembly 2, and the groove 13 may be provided on the side of the second substrate 12 close to the encapsulation assembly 2. The encapsulation assembly 2 is provided within the groove 13 on the first substrate 11 and the second substrate 12, and the encapsulation assembly 2 is pressed together with the first substrate 11 and the second substrate 12 for encapsulation. The pressed encapsulation can be pressing and heating. The first substrate 11 and the second substrate 12 are heated, such that the encapsulation assembly 2 can be fully combined with the first substrate 11 and the second substrate 12, and their connections can be more close, so as to reduce the possibility of the encapsulation assembly 2 falling off from the first substrate 11 and the second substrate 12.

When a large amount of moisture gathers on the surface of the encapsulation assembly 2, the moisture slides down along the curved surface of the bending deformation portion 211 into the groove 13 to prevent the moisture from adhering to the surface of the encapsulation assembly 2 for a long period of time to form an infiltration of the encapsulation assembly 2, thereby avoiding the moisture entering the display region to cause oxidative corrosion to the structure in the display region, so that the service life of the display module 1 can be extended.

In the embodiments of the present application, through holes may also be provided in the first substrate 11 and the second substrate 12, and the through holes are connected to the groove 13, so that the moisture within the groove 13 may be discharged to the outside of the display module 1 through the through holes, thereby reducing the accumulation of moisture within the groove 13, and reducing the possibility of moisture penetrating the encapsulation assembly 2 to enter into the display region.

In addition, a layer of waterproof material with tension can be coated on the inner wall of the groove 13, so that when the encapsulation assembly 2 is pressed by an external force, the tension of the elastic encapsulation member 21 and the waterproof material can offset a portion of the pressed force, thereby reducing the deformation of the encapsulation assembly 2 under the pressing of the external force, and thus reducing the possibility of occurrence of a gap between the encapsulation assembly 2 and the first substrate 11 and the second substrate 12. The waterproof material coated on the inner wall of the groove 13 may form a barrier to moisture, thereby reducing the possibility of moisture penetrating through the first substrate 11 and the second substrate 12 to enter into the display region.

As shown in FIG. 4, in this embodiment of the present application, an evaporation member 23 may be provided in the encapsulation assembly 2, and the evaporation member 23 is provided at least on the side of the elastic encapsulation member 21 close to the first substrate 11, or the side of the elastic encapsulation member 21 close to the second substrate 12.

It is to be noted that the evaporation member 23 in the embodiments of the present application may adopt a material that is conductive when meeting the moisture, and when the evaporation member 23 is in contact with the moisture, the evaporation member 23 conducts electricity and heat, thereby drying the moisture and providing a dry environment for the encapsulation assembly 2, reducing a possibility of the encapsulation assembly 2 in a wet environment for a long time to cause the penetration of the moisture into the encapsulation assembly 2, and reducing a possibility of the moisture leading to weakening adhesive of the encapsulation assembly 2 and the first substrate 11 and the second substrate 12, thereby reducing the risk of the moisture entering the display region to cause oxidative corrosion to the structure of the display region. When the evaporation member 23 is not in contact with the moisture, the evaporation member 23 is not electrically conductive, which may reduce the energy consumption of the evaporation member 23 and reduce the situation that the display module 1 has an excessively high temperature caused by the conductive heat of the evaporation member 23, thereby saving the cost of use of the encapsulation assembly 2, and reducing the risk of the service life of the display module 1 being reduced due to high temperature.

In addition, the display module 1 in the embodiments of the present application includes a common voltage (Vcom) wire 18, which may provide a voltage for the display module 1 to control the display of the display module 1. The common voltage wire 18 is usually distributed in the outer side of the display region, and therefore, the embodiments of the present application may connect the evaporation member 23 to the common voltage wire 18, and specifically, may connect an end of the evaporation member 23 to the common voltage wire 18 (not shown in the figures), ground another end of the evaporation member 23 to form a complete circuit, and may allow the common voltage wire 18 to provide voltage to the evaporation member 23.

The evaporation member 23 may realize the connection with the common voltage wire 18 directly at the common voltage routing plane layer where the common voltage wire 18 is provided, but is not limited to this, and an independent plane layer may be established in addition to the common voltage routing plane layer, and the common voltage wire 18 and the evaporation member 23 may be hauled to the independent plane layer to realize the connection between the common voltage wire 18 and the evaporation member 23, to reduce affection on the connection wire between the common voltage wire 18 and the evaporation member by electromagnetic interference from other circuits.

An end of the evaporation member 23 connected to the common voltage wire 18 may be realized by a conductive gold ball to realize the circuit connection, but is not limited thereto, and may also be realized by conductive structures other than the conductive gold ball to realize the circuit connection between the evaporation member 23 and the common voltage wire 18.

A grounded end of the evaporation member 23 may be provided with a silver adhesive dot 19, and the evaporation member 23 may be grounded through the silver adhesive dot 19 to conduct the electrostatic charge into the earth, thereby reducing the risk of electrostatic disruption of the normal operation of the circuit, or even damage to the sensitive electronic components, but is not limited to this. The grounded end of the evaporation member 23 may be provided with a grounding device other than the silver adhesive dot 19, in order to conduct the electrostatic charge into the earth. The silver adhesive dot 19 may be provided in a non-display region, specifically, the silver adhesive dot 19 may be provided on a side of the first substrate 11 or the second substrate 12 away from the display region to facilitate the evaporation member 23 to conduct the electrostatic charge into the earth through the silver adhesive dot 19, and to reduce the shielding of the display region to contribute to the narrow frame design of the display module 1.

Since the evaporation member 23 is connected to the common voltage wire 18, the embodiment of the present application can directly use the voltage provided by the common voltage wire 18 to supply power to the evaporation member 23, avoiding setting up a separate connection wire to supply power to the evaporation member 23, so as to simplify the manufacturing process of the encapsulation assembly 2 and reduce the manufacturing cost of the encapsulation assembly 2. Without being limited thereto, the evaporation member 23 can also be connected to a wire other than the common voltage wire 18 to obtain voltage and to realize the function of conducting electricity and heat when meeting water.

The evaporation member 23 in the embodiments of the present application may be provided in the groove 13, specifically, the evaporation member 23 may be buried in the vacant position of the groove 13 after the encapsulation assembly 2 is pressed and fitted in the groove 13, and the evaporation member 23 may be connected to the common voltage wire 18. The evaporation member 23 may dry the moisture on the groove 13 and the encapsulation assembly 2, so as to reduce the possibility of the moisture entering into the display region, and reduce the risk of oxidative corrosion to the structure in the display region by the moisture. In the groove 13, one evaporation member 23 may be provided, but not limited to this, and a plurality of evaporation members 23 may be provided inside the groove 13, the evaporation members 23 are connected to the common voltage wire 18 respectively. The plurality of evaporation members 23 inside the groove 13 can enlarge the drying range of the evaporation members 23 for the groove 13 and the encapsulation assembly 2, so as to further reduce the possibility of the moisture entering into the display region.

Further, as shown in FIG. 5, the display module 1 in the embodiment of the present application may also include a light emitting layer 16, a cathode 15, and an anode 14 provided in the display region, and the cathode 15 and the anode 14 are provided between the first substrate 11 and the second substrate 12, and the cathode 15 corresponds to the anode 14.

Specifically, the anode 14 may be provided on a side of the cathode 15 away from the second substrate 12, but is not limited thereto, and the anode 14 may be provided on a side of the cathode 15 away from the first substrate 11, and the light emitting layer 16 is provided between the cathode 15 and the anode 14 and connected to the cathode 15 and the anode 14.

The light emitting layer 16 may be an organic self-luminous material, and under the excitation of the voltage formed by the anode 14 and the cathode 15, the light emitting layer 16 emits visible light through the compounding process of electrons and holes, so as to enable the display module 1 to display a picture, but is not limited thereto. The light emitting layer 16 may be made of a material other than the organic self-luminous material, for example, the light emitting layer 16 may be filled with liquid crystal molecules, and the deflection of the liquid crystal molecules can be controlled to control the display of the display module 1.

It should be noted that, in order to reduce the electron injection barrier, the cathode 15 is usually made of a chemically more active metal with a low work function, which is easily oxidized and thus prone to cause a problem of reducing life of the device. When the light emitting layer 16 is an organic self-luminous material sensitive to the moisture and oxygen, and thus the organic self-luminous material is susceptible to aging and denaturation due to the moisture and oxygen, resulting in a significant degradation of the brightness and life of the device. As a result, the structure located within the display region is easily oxidized and corroded when it is in contact with external moisture.

The encapsulation assembly 2 is provided in the preset disclosure, the encapsulation assembly 2 and the first substrate 11 and the second substrate 12 together enclose the display region to form a closed space, to form a barrier between the structure in the display region and the outside, to reduce the contact between the structure in the display region and the external moisture, so as to reduce the possibility of occurrence of oxidative corrosion after the cathode 15, the organic self-luminous material and other structures in the display region contact the moisture, to slow down the rate at which the display brightness of the organic self-luminous material decreases, and slowing down the rate at which the organic self-luminous material and the cathode 15 are oxidized and corroded, so as to improve the service life of the display module 1.

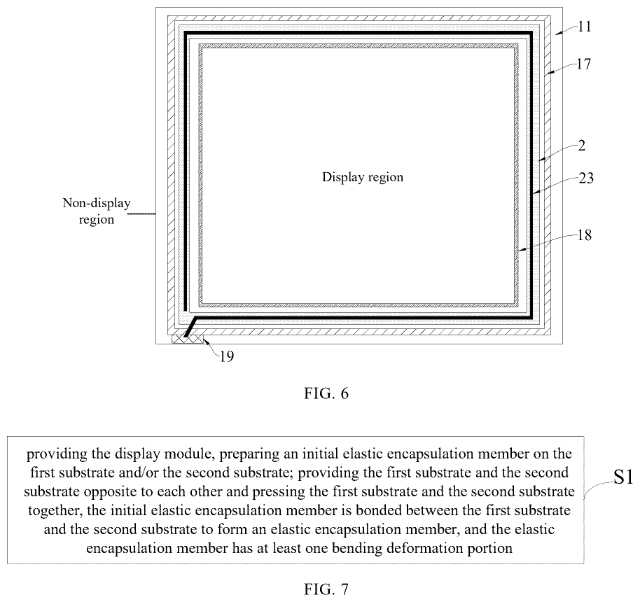

In addition, as shown in FIGS. 5 and 6, the display module 1 may also include a frame adhesive 17, the frame adhesive 17 is connected to the first substrate 11 and the second substrate 12, respectively, and the frame adhesive 17 is located in the non-display region and is provided around a peripheral side of the encapsulation assembly 2. Since the frame adhesive 17 around the peripheral side of the encapsulation assembly 2 is provided, the encapsulation of the display region may be further strengthened, reducing the possibility of the external moisture entering into the display region to cause oxidative corrosion to the structure in the display region, to extend the service life of the display module 1.

As shown in FIG. 7, embodiments of the present application also provide a method of manufacturing an encapsulation assembly 2, the encapsulation assembly 2 is used to encapsulate a display module 1. The display module 1 includes a first substrate 11 and a second substrate 12 opposite to each other, and the display module 1 further includes a display region and a non-display region provided around the display region. The method for manufacturing the encapsulation assembly 2 includes:

S1, providing the display module 1, preparing an initial elastic encapsulation member on the first substrate 11 and/or the second substrate 12; providing the first substrate 11 and the second substrate 12 opposite to each other and pressing the first substrate and the second substrate together, the initial elastic encapsulation member is bonded between the first substrate 11 and the second substrate 12 to form an elastic encapsulation member 21, and the elastic encapsulation member 21 has at least one bending deformation portion 211.

It is to be noted that the manufacturing method in the embodiments of the present application can manufacture any of the above encapsulation assemblies 2, and the encapsulation assemblies 2 formed by utilizing the manufacturing method in the embodiments of the present application can be used to encapsulate any of the above display modules 1.

Specifically, an initial elastic encapsulation member may be prepared on the first substrate 11 only, and the first substrate 11 and the second substrate 12 may be provided opposite to each other and pressed together to form the elastic encapsulation member 21, such that the elastic encapsulation member 21 is bonded between the first substrate 11 and the second substrate 12.

In embodiments of the present application, it is also possible to prepare the initial elastic encapsulation member only on the second substrate 12, and provide the first substrate 11 and the second substrate 12 opposite to each other and press them to form the elastic encapsulation member 21, such that the elastic encapsulation member 21 is bonded between the first substrate 11 and the second substrate 12.

However, without limitation, embodiments of the present application may also prepare the initial elastic encapsulation member on the first substrate 11 and the second substrate 12 respectively, and then provide the first substrate 11 and the second substrate 12 opposite to each other and press them together, and after the pressing, the initial elastic encapsulation member on the first substrate 11 and the initial elastic encapsulation member on the second substrate 12 correspond to each other one-in-one and are connected to each other to form the elastic encapsulation member 21, and after the elastic encapsulation member 21 is formed, the elastic encapsulation member 21 is bonded between the first substrate 11 and the second substrate 12.

Further, the forming the initial elastic encapsulation member may include: providing a mold on at least one of the first substrate 11 and the second substrate 12, filling the mold with the initial elastic encapsulation member, and initially curing the initial elastic encapsulation member.

Specifically, when preparing the initial elastic encapsulation member on the first substrate 11 only, the mold may be provided on the first substrate 11 only. When preparing the initial elastic encapsulation member only on the second substrate 12, the mold may be provided only on the second substrate 12. When preparing the initial elastic encapsulation members on the first substrate 11 and the second substrate 12 respectively, the molds may be provided on the first substrate 11 and the second substrate 12 respectively, and the molds on the first substrate 11 and the second substrate 12 correspond to each other one-in-one, so that the initial elastic encapsulation members on the two substrates may be connected correspondingly to form the elastic encapsulation member 21 after the first substrate 11 and the second substrate 12 are pressed together.

It is to be illustrated that the mold in the embodiments of the present application is hollow and the sidewalls of the mold are curved, so that the initial elastic encapsulation member formed can be of a curved shape, and the initial curing of the initial elastic encapsulation member can be carried out to make the curved shape of the initial elastic encapsulation member basically stereotyped.

When the mold is a soft mold, after the initial elastic encapsulation member is cured initially, the mold may be removed and the filling member 22 may be provided between adjacent initial elastic encapsulation members, but not limited thereto. The mold may be retained after the initial elastic encapsulation member is cured initially to reduce the step of removing the mold, thereby simplifying the formation process of the encapsulation assembly 2, and avoiding damage to the initial elastic encapsulation member when the mold is removed. In addition, after the first substrate 11 and the second substrate 12 are pressed together to form the elastic encapsulation member 21, The mold can also form a support for the elastic encapsulation member 21 to improve the compression resistance of the encapsulation assembly 2, reduce the deformation of the elastic encapsulation member 21, and reduce the possibility of occurrence of a gap between the elastic encapsulation member 21 and the first substrate 11 or the second substrate 12, so that the risk of the moisture entering into the display region to cause oxidative corrosion to the structure in the display region can be reduced, to extend the service life of the display module 1.

To illustrate, the soft mold may be made of a silicone rubber material, but is not limited to this, and the use of other soft materials with less structural strength to make the soft mold is also included in the scope of the embodiments of the present application.

When the mold is a rigid mold, after the initial elastic encapsulation member is cured initially, the mold may be retained. The mold may be used to form a support for the initial elastic encapsulation member to improve the compression resistance of the initial elastic encapsulation member, to reduce the amount of deformation of the initial elastic encapsulation member, and reduce the possibility of occurrence of the gap between the initial elastic encapsulation member and the first substrate 11 or the second substrate 12, so that the risk of the moisture entering into the display region to cause oxidative corrosion to the structure in the display region can be reduced, to extend the service life of the display module 1. Without limitation, the mold may also be removed after the initial elastic encapsulation member is cured initially. After the initial elastic encapsulation member is formed using the mold, the removing or retention of the mold may be determined according to the actual situation.

To illustrate, the rigid mold may be made of an acrylic material, but is not limited thereto, and the use of other rigid materials with greater structural strength to make the rigid mold is also included within the scope of the embodiments of the present application.

In embodiments of the present application, if the mold is removed after the initial elastic encapsulation member is initially cured, the filling member 22 may be provided between adjacent initial elastic encapsulation members. The structural strength of the filling member 22 may be greater than the structural strength of the initial elastic encapsulation member, so that when the initial elastic encapsulation member is subjected to an external pressure, the filling member 22 may form a support for the initial elastic encapsulation member to improve the pressure resistance of the initial elastic encapsulation member, to reduce the amount of deformation of the initial elastic encapsulation member, to reduce the possibility of occurrence of the gap between the initial elastic encapsulation member and the first substrate 11 or the second substrate 12, thereby reducing the risk of the moisture entering the display region to cause oxidative corrosion to the structure in the display region, so as to extend the service life of the display module 1.

Before providing the mold, a buffer layer is provided on the first substrate 11 and/or the second substrate 12.

Specifically, the buffer layer may be provided on the first substrate 11 only, or the buffer layer may be provided on the second substrate 12 only, but without limitation, or the buffer layer may be provided on both the first substrate 11 and the second substrate 12, which is determined based on actual situations.

When the first substrate 11 and the second substrate 12 are pressed together, the buffer layer is provided between the first substrate 11 and the mold, and between the second substrate 12 and the mold, which can play the role of buffering and shock absorption.

Specifically, when the mold is retained in the encapsulation assembly 2, the buffering member can reduce the collision and friction between the mold and the first substrate 11 and the second substrate 12 when the encapsulation assembly 2 is subjected to external impacts or vibrations, thereby reducing the possibility of the damage to the mold and the first substrate 11 and the second substrate 12, to extend the service life of the encapsulation assembly 2 and the display module 1.

When the mold is removed from the encapsulation assembly 2, if the filling member 22 is provided between adjacent initial elastic encapsulation members, the buffer layer can reduce the collision and friction between the filling member 22 and the first substrate 11 or the second substrate 12 when the encapsulation assembly 2 is subjected to external impacts or vibrations, so as to reduce the possibility of damage to the filling member 22, the first substrate 11 and the second substrate 12, to extend the service life of the encapsulation assembly 2 and the display module 1.

After pressing together the first substrate 11 and the second substrate 12, or during the process of pressing together the first substrate 11 and the second substrate 12, the initial elastic encapsulation member is cured again to form the elastic encapsulation member 21.

To illustrate, the initial curing of the initial elastic encapsulation member and the re-curing of the initial elastic encapsulation member may be performed using one or more of a heat curing, UV curing, or moisture curing process, without specific limitation herein. When the initial elastic encapsulation member is cured by the heat curing process, the initial elastic encapsulation member may slightly expand during the heat process, to facilitate attachment to the substrate and reduce the possibility of occurrence of the gap between the initial elastic encapsulation member, the first substrate 11, and the second substrate 12.

In addition, embodiments of the present application may also form the initial elastic encapsulation member directly on at least one of the first substrate 11 and the second substrate 12 without using a mold. Specifically, the material of the initial elastic encapsulation member may be stored in a glue reservoir, and the glue tip may be swung back and forth as the glue is dripped on the first substrate 11 and/or the second substrate 12 to achieve a bending effect of the initial elastic encapsulation member formed on the substrates. The manufacturing method of forming the initial elastic encapsulation member directly by swinging the glue tip back and forth without using a mold may be applicable to the embodiment in which the elastic encapsulation members 21 are sequentially abutted, but is not limited to this, and the manufacturing method in which the glue tip is swung back and forth may be used to form the initial elastic encapsulation member in the embodiment in which the elastic encapsulation members 21 are provided at intervals.

Embodiments of the present application also provide a display device, the display device includes any one of the encapsulation assembly 2 and the display module 1 as described above, and since the encapsulation assembly 2 is provided in a non-display region of the display module 1, the encapsulation assembly 2, the first substrate 11 and the second substrate 12 together enclose the display region to form a closed space, thereby reducing the possibility of the external moisture entering into the display region to cause oxidative corrosion of the structure of the display region, to extend the service life of the display device.

It is to be noted that the display module 1 in the embodiments of the present application may be applicable to an organic light emitting diode (OLED) display device or a liquid crystal (LCD) display device, and is not specifically limited herein.

In addition, the terms “first”, “second”, and “third” are used for descriptive purposes only, and are not to be understood as indicating or implying relative importance or implicitly specifying the number of the indicated technical features. Thus, a feature defined with “first”, “second”, and “third” may expressly or implicitly include one or more such features. In the description of the present application, “more than one” means two or more, unless otherwise expressly and specifically limited.

It should be noted that “up”, “down”, “left”, “right”, etc. are only used as distinctions to facilitate description. It does not limit the embodiments of the present application in terms of orientation, for example, the “up” may be “down”, “left”, “right” and other orientations in practice. In the present application, unless otherwise expressly provided and limited, the terms “assembly”, “connection”, etc. shall be broadly construed, e.g., it may be a fixed connection, a detachable connection, or formed integratedly, or a mechanical connection, or an electrical connection, a direct connection or an indirect connection through an intermediate medium, a connection within two elements or an interactive relationship between two elements. For those skilled in the art, the specific meanings of the above terms in the present application may be understood based on the actual situation.

In the description of the present specification, the description with reference to the terms “some embodiments”, “exemplarily”, etc. means that the specific features, structures, materials, or characteristics described in conjunction with the embodiment or exemplary example are included in at least one embodiment or exemplary example of the present application. In this specification, schematic expressions of the above terms need not be directed to the same embodiment or example. Moreover, the specific features, structures, materials, or characteristics described may be combined in any one or more embodiments or examples in a suitable manner. Moreover, without contradicting each other, those skilled in the art may combine different embodiments or examples and features of different embodiments or examples described in this specification.

What is claimed is:

1. An encapsulation assembly, for encapsulating a display module, wherein the display module comprises a first substrate and a second substrate opposite to each other, and the display module further comprises a display region and a non-display region provided around the display region;
wherein the encapsulation assembly comprises an elastic encapsulation member, provided between the first substrate and the second substrate and located in the non-display region, wherein the elastic encapsulation member comprises two bending deformation portions connected to each other and bent in opposite directions;
wherein one of the two bending deformation portions is connected to the first substrate, and another one of the two bending deformation portions is connected to the second substrate;
wherein a plurality of elastic encapsulation members are sequentially arranged between the non-display region and the display region in a direction from the non-display region to the display region; and
wherein the plurality of elastic encapsulation members are sequentially abutted against each other, two adjacent bending deformation portions are bent in a same direction, and a concave surface of one of the two adjacent bending deformation portions is closely spliced with a convex surface of another one of the two adjacent bending deformation portions.

2. The encapsulation assembly according to claim 1, wherein each of the first substrate and the second substrate is provided with a groove on a side close to the encapsulation assembly, and the encapsulation assembly is provided within the groove.

3. The encapsulation assembly according to claim 1, wherein the encapsulation assembly comprises an evaporation member located at least on a side of the elastic encapsulation member close to the first substrate, or on a side of the elastic encapsulation member close to the second substrate, wherein the evaporation member is heated by water.

4. The encapsulation assembly according to claim 3, wherein the display module comprises a common voltage wire connected to the evaporation member to supply power to the evaporation member.

5. The encapsulation assembly according to claim 1, wherein the display module comprises a cathode, an anode and a light emitting layer provided in the display region, wherein the cathode and the anode are provided between the first substrate and the second substrate, and the cathode corresponds to the anode, and the light emitting layer is provided between the cathode and the anode and connected to the cathode and the anode; and/or
the display module comprises a frame adhesive connected to the first substrate and the second substrate, wherein the frame adhesive is provided in the non-display region and provided around an outer peripheral side of the encapsulation assembly.

6. The encapsulation assembly according to claim 1, wherein the elastic encapsulation member is provided around the display region and connected to the first substrate and the second substrate, and the elastic encapsulation member, the first substrate, and the second substrate enclose to form a closed space for isolating the display region of the display module from an outside.

7. The encapsulation assembly according to claim 1, wherein the elastic encapsulation member is provided with one or more than three bending deformation portions, and the two bending deformation portions connected to each other are bent in opposite directions;
the bending deformation portions in the elastic encapsulation member are connected to the first substrate and the second substrate, respectively, and form a support for the first substrate and the second substrate.

8. The encapsulation assembly according to claim 1, wherein the plurality of elastic encapsulation members are sequentially arranged from the non-display region to the display region.

9. The encapsulation assembly according to claim 8, wherein when the plurality of elastic encapsulation members are spaced apart, the encapsulation assembly further comprises a filling member, the filling member is provided between two adjacent elastic encapsulation members.

10. The encapsulation assembly according to claim 1, wherein through holes are provided in the first substrate and the second substrate, and the through holes are connected to a groove, to make moisture within the groove be discharged to outside of the display module through the through holes.

11. The encapsulation assembly according to claim 2, wherein a layer of waterproof material with tension is coated on an inner wall of the groove.

12. The encapsulation assembly according to claim 3, wherein a grounded end of the evaporation member is provided with a silver adhesive dot, and the evaporation member is grounded through the silver adhesive dot to conduct electrostatic charge into an earth.

13. A method for manufacturing an encapsulation assembly, wherein the encapsulation assembly is configured for encapsulating a display module, wherein the display module comprises a first substrate and a second substrate opposite to each other, and the display module further comprises a display region and a non-display region provided around the display region;
wherein the method comprises:
providing the display module, and preparing an initial elastic encapsulation member on the first substrate and/or the second substrate;
providing the first substrate and the second substrate opposite to each other and pressing the first substrate and the second substrate together, wherein the initial elastic encapsulation member is bonded between the first substrate and the second substrate to form an elastic encapsulation member, the elastic encapsulation member has two bending deformation portions connected to each other, the two bending deformation portions are bent in opposite directions, one of the two bending deformation portions is connected to the first substrate, and another one of the two bending deformation portions is connected to the second substrate; and
arranging a plurality of elastic encapsulation members sequentially in a direction from the non-display region to the display region;
wherein two adjacent elastic encapsulation members are sequentially abutted against each other, two adjacent bending deformation portions are bent in a same direction, and a concave surface of one of the two adjacent bending deformation portions is closely spliced with a convex surface of another one of the two adjacent bending deformation portions.

14. The method according to claim 13, wherein forming the initial elastic encapsulation member comprises:
providing a mold on the first substrate and/or the second substrate, wherein the mold is hollow and sidewalls of the mold are curved;
filling the mold with the initial elastic encapsulation member, and initially curing the initial elastic encapsulation member;
when the mold is a soft mold, after initially curing the initial elastic encapsulation member, removing the mold and providing a filling member between adjacent initial elastic encapsulation members;
when the mold is a rigid mold, retaining the mold; and/or
providing a buffer layer on the first substrate and/or the second substrate before providing the mold; and
after pressing the first substrate and the second substrate or during pressing, curing the initial elastic encapsulation member again to form the elastic encapsulation member.

15. A display device, comprising an encapsulation assembly and a display module, wherein the encapsulation assembly is configured for encapsulating the display module, and the display module comprises a first substrate and a second substrate opposite to each other, and the display module further comprises a display region and a non-display region provided around the display region;
wherein the encapsulation assembly comprises an elastic encapsulation member, provided between the first substrate and the second substrate and located in the non-display region, wherein the elastic encapsulation member comprises two bending deformation portions connected to each other and bent in opposite directions;
wherein one of the two bending deformation portions is connected to the first substrate, and another one of the two bending deformation portions is connected to the second substrate;
wherein a plurality of elastic encapsulation members are sequentially arranged between the non-display region and the display region in a direction from the non-display region to the display region; and
wherein the plurality of elastic encapsulation members are sequentially abutted against each other, two adjacent bending deformation portions are bent in a same direction, and a concave surface of one of the two adjacent bending deformation portions is closely spliced with a convex surface of another one of the two adjacent bending deformation portions.

16. The display device according to claim 15, wherein each of the first substrate and the second substrate is provided with a groove on a side close to the encapsulation assembly, and the encapsulation assembly is provided within the groove.

17. The display device according to claim 15, wherein the encapsulation assembly comprises an evaporation member located at least on a side of the elastic encapsulation member close to the first substrate, or on a side of the elastic encapsulation member close to the second substrate, wherein the evaporation member is heated by water.

18. The display device according to claim 17, wherein the display module comprises a common voltage wire connected to the evaporation member to supply power to the evaporation member.

19. The display device according to claim 15, wherein the display module comprises a cathode, an anode and a light emitting layer provided in the display region, wherein the cathode and the anode are provided between the first substrate and the second substrate, and the cathode corresponds to the anode, and the light emitting layer is provided between the cathode and the anode and connected to the cathode and the anode; and/or
the display module comprises a frame adhesive connected to the first substrate and the second substrate, wherein the frame adhesive is provided in the non-display region and provided around an outer peripheral side of the encapsulation assembly.
